(19) United States
(12) Patent Application Publication
(10) Pub. No.: US 2013/0155639 A1
(43) Pub. Date: Jun. 20, 2013

(54) ELECTRONIC COMPONENT AND METHOD FOR MANUFACTURING THE SAME

(71) Applicant: Murata Manufacturing Co., Ltd., Nagaokakyo-shi (JP)

(72) Inventors: Nobuaki OGAWA, Nagaokakyo-shi (JP); Yoshihito OTSUBO, Nagaokakyo-shi (JP)

(73) Assignee: MURATA MANUFACTURING CO., LTD., Nagaokakyo-shi (JP)

(21) Appl. No.: 13/766,805

(22) Filed: Feb. 14, 2013

Related U.S. Application Data
(63) Continuation of application No. PCT/JP2011/063202, filed on Jun. 9, 2011.

(30) Foreign Application Priority Data
Aug. 18, 2010 (JP) 2010-183117

(51) Int. Cl. H05K 9/00; H05K 13/04

(52) U.S. Cl. CPC H05K 9/0024; H05K 13/04
USPC 361/816; 29/841

(57) ABSTRACT

An electronic component includes a substrate, first electronic components mounted on a first principle surface of the substrate, a first resin layer that covers the first principal surface of the substrate and the first electronic components, a second electronic component mounted on a second principle surface of the substrate, a second resin layer that covers the second principal surface of the substrate and the second electronic component, an electrically conductive shield layer, and a ground electrode arranged in the substrate so as to reach a side surface of the substrate. The shield layer is a single continuous layer that covers the first resin layer, the side surface of the substrate, and a portion of the second resin layer adjacent to the substrate. The shield layer is in contact with and electrically connected to the ground electrode.

### BACKGROUND OF THE INVENTION

1. Field of the Invention

The present invention relates to electronic components and their manufacturing methods, and more particularly, to electronic components including shield layers and their manufacturing methods.

2. Description of the Related Art

One prior art has proposed a structure of an electronic component 110, as illustrated in FIG. 7, in which resin layers 114, 115 are arranged on both top and bottom surfaces of a substrate 111, and components 112, 113 are buried inside the resin layers 114, 115. In that structure, a metal-film shield layer 116 is formed on a top surface of the resin layer 114. The shield layer 116 is connected to a ground electrode (not illustrated in the figure) formed on the top surface of the substrate 114 via a connection terminal 117 that penetrates through the resin layer 111 (for example, see Japanese Patent No. 4042785).

To form the structure of FIG. 7, it is necessary to perform a step to form the connection terminal 117 inside the resin layer 114, namely, a step that is performed solely for making an electrical connection between the shield layer 116 and the substrate 111. This leads to an increase in manufacturing cost. Furthermore, it is necessary to form the ground electrode on the top surface of the substrate 111 to electrically connect the substrate 111 and the shield layer 116. This imposes constraints in substrate designing.

### SUMMARY OF THE INVENTION

In view of the above, preferred embodiments of the present invention provide an electronic component and a manufacturing method thereof, each of which is capable of reducing the manufacturing cost and providing more flexibility in substrate designing.

An electronic component according to a preferred embodiment of the present invention includes a substrate including a first principle surface, a second principle surface that faces the first principle surface, and a side surface that extends between the first and the second principle surfaces; a first electronic component mounted on the first principle surface of the substrate; a second electronic component mounted on the second principle surface of the substrate; a first resin layer arranged on the first principle surface of the substrate so as to cover the first principle surface and the first electronic component; a second resin layer formed on the second principle surface of the substrate so as to cover the second principle surface and the second electronic component; a shield layer that is electrically conductive and defines a single continuous layer covering the first resin layer, the substrate, and a portion of the second resin layer that is adjacent to the substrate; and a ground electrode that is arranged in the substrate so as to reach the side surface of the substrate, the ground electrode being in contact with the shield layer and electrically connected to the shield layer.

According to the foregoing structure, the formation of the shield layer and the connection of the shield layer to the ground electrode that reaches the side surface of the substrate, may be achieved at the same time. This eliminates the need for the step that is performed solely for establishing an electrical connection between the shield layer and the substrate. The shield layer is electrically connected to the ground electrode at the side surface of the substrate. Thus, it is not necessary to form any ground electrode on the first principle surface of the substrate to connect with a connection terminal that penetrates through the first resin layer.

Preferably, the second resin layer may include a first principle layer that is in contact with the second principle surface of the substrate, a second principle surface that faces the first principle surface, and a side surface that extends between the first principle surface and the second principle surface. The shield layer may be formed on the side surface of the second resin layer so as to have a space between the shield layer and the second principle surface of the second resin layer.

In this case, a space is preferably provided between the shield layer and another circuit board or the like when an outer electrode is formed to mount the electronic component to the another circuit board or the like. Thus, insulation between the shield layer and the another circuit board or the like may be easily secured.

Preferably, the shield layer may be made of an electrically conductive resin.

The use of the electrically conductive resin makes it possible to form the shield layer easily compared to the case where the shield layer is formed by using a method that uses a metal foil.

A method for manufacturing an electronic component according to another preferred embodiment of the present invention includes a first step of preparing a multi-piece board including a substrate including a first principle surface and a second principle surface that faces the first principle surface, wherein the substrate includes plural portions that are to be separated and become plural individual boards; in each of the plural portions that become the individual boards, a ground electrode is formed so as to reach an outer edge of the portion that becomes the individual boards; in each of the plural portions that become the individual boards, a first electronic component is mounted on the first principle surface; in each of the plural portions that become the individual boards, a second electronic component is mounted on the second principle surface; a first resin layer is formed on the first principle surface so as to cover the first principle surface and the first electronic component; and a second resin layer is formed on the second principle surface so as to cover the second principle surface and the second electronic component; a second step of forming closed-bottom trenches in the multi-piece board by cutting the first resin layer, the substrate, and a portion of the second resin layer on a substrate side from a principle surface of the first resin layer, which is opposite to the substrate, so that the substrate is separated into the individual boards, the second step exposing the ground electrode at a cut surface of the substrate; (iii) a third step of forming a shield layer inside the closed-bottom trenches and on the principle surface of the first resin layer, which is on the side opposite to the substrate, by using an electrically conductive material so that the shield layer is in contact with and electrically connected to the ground electrode thus exposed; and (iv) a fourth step of separating the multi-piece board into individual pieces by cutting the multi-piece board along peripheries of the individual boards along which the substrate is separated.

In the foregoing third step, the formation of the shield layer and the connection of the shield layer to the ground electrode, which is exposed at the cut surface of the substrate, may be achieved at the same time. This eliminates the need for the step that is performed solely to establish an electrical connection between the shield layer and the substrate. The shield layer is electrically connected to the ground electrode at the cut surface of the substrate. Thus, it is not necessary to form any ground electrode on the first principle surface of the substrate to connect with a connection terminal that penetrates through the first resin layer.

According to a preferred embodiment of the present invention, the step that is performed solely to establish an electrical connection between the shield layer and the substrate may be eliminated, and the manufacturing cost may be reduced. Furthermore, it is not necessary to form any ground electrode on the first principle surface of the substrate to connect with a connection terminal that penetrates through the first resin layer. This facilitates more flexibility in designing of the substrate when compared to the case where the ground electrode is formed on the first principle surface of the substrate to connect with the connection terminal that penetrates through the first resin layer.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are cross-sectional diagrams illustrating manufacturing steps of an electronic component (Example 1).

FIGS. 2C and 2D are cross-sectional diagrams illustrating manufacturing steps of the electronic component (Example 1).

FIG. 3 is an enlarged cross-sectional diagram illustrating an electronic component (Example 1).

FIG. 4 is a cross-sectional diagram illustrating an electronic component (Example 1).

FIG. 5 is a cross-sectional diagram illustrating an electronic component (Example 2).

FIG. 6 is a cross-sectional diagram illustrating an electronic component (Example 3).

FIG. 7 is a cross-sectional diagram illustrating an electronic component (Prior Art).

### DETAILED DESCRIPTION OF THE PREFERRED EMBODIMENTS

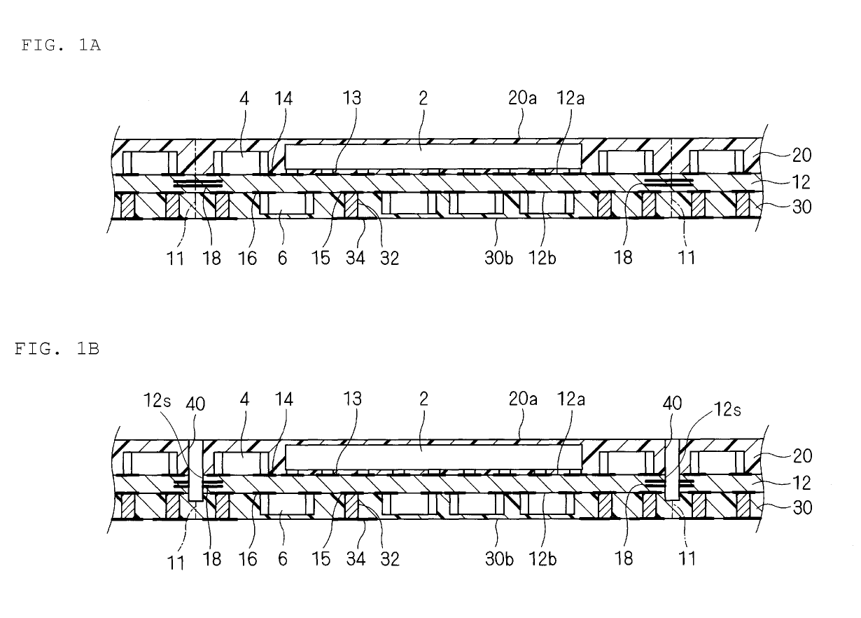

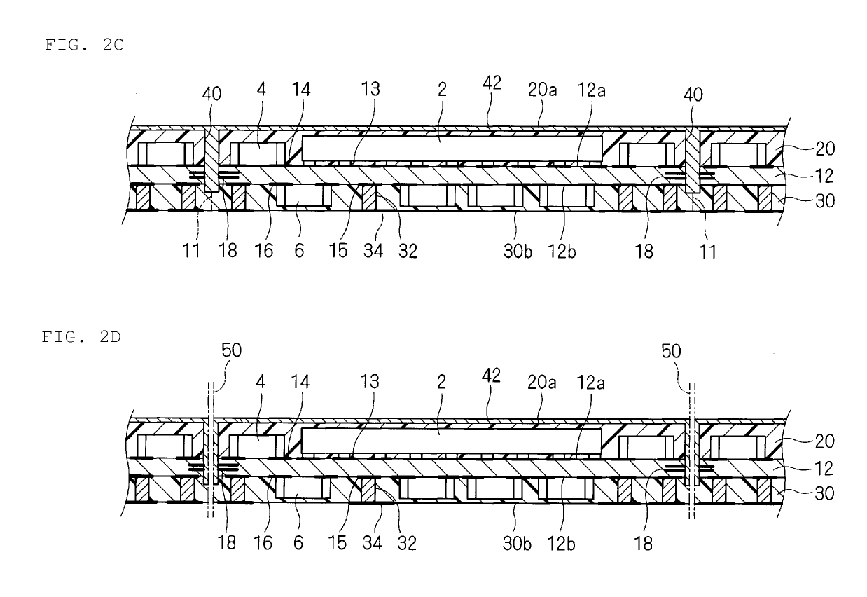

Hereinafter, preferred embodiments of the present invention will be described with reference to FIG. 1A-FIG. 6.

### Example 1

An electronic component 10 of Example 1 of a preferred embodiment of the present invention will now be described with reference to FIG. 1A-FIG. 4.

FIG. 4 is a cross-sectional diagram of the electronic component 10. As illustrated in FIG. 4, in the electronic component 10, a top surface 12a that serves as a first principle surface of a substrate 12 and first electronic components 2, 4 mounted on the top surface 12a are coated with a first resin layer 20. Furthermore, a bottom surface 12b that serves as a second principle surface of the substrate 12 and second electronic components 6 mounted on the bottom surface 12b are coated with a second resin layer 30. The electronic components 2, 4, 6 to be mounted on the top surface 12a and the bottom surface 12b of the substrate 12 are surface mount components, and may be, for example, active devices such as semiconductors, etc., or passive devices such as capacitors, inductors, resistors, etc. The electronic components 2, 4, 6 are each sealed by the resin layer 20 or 30.

Outer electrodes 34 are provided on a bottom surface 30b of the second resin layer 30 to mount the electronic component 10 to another circuit board or the like. The outer electrodes 34 are electrically connected to terminal electrodes 15 provided on the bottom surface 12b of the substrate 12 via connection terminals 32 which penetrate through the second resin layer 30.

The substrate 12 may be a ceramic substrate or a resin substrate made of glass epoxy or the like, and is provided with mounting electrodes 13, 14, 16 provided on the top surface 12a and the bottom surface 12b to mount the electronic components 2, 4, 6.

Ground electrodes 18 are arranged inside the substrate in such a way that they reach side surfaces 12s of the substrate 12. The ground electrode 18 is grounded by electrically connecting to the terminal electrode 15 provided on the bottom surface 12b of the substrate 12 via a wiring pattern or an inter-layer connecting conductor, which is located inside the substrate 12 and not illustrated in the figure, and then through the connection terminal 32 and the outer electrode 34.

If the substrate 12 preferably is a ceramic multilayer substrate, a high density wiring formation may be achieved. Thus, the thickness of substrate may be reduced, and the profile of the electronic component 10 may be flattened. Typically, a ceramic substrate breaks easily when it is made thin. However, the ceramic multilayer substrate that serves as the substrate 12 may be made thin because the substrate 12 is reinforced by the resin layers 20, 30 arranged on both sides thereof and protected from being broken.

The thermal conductivity of the resin layers 20, 30 is enhanced by mixing an inorganic compound such as silica or the like as filler with a synthetic resin such as epoxy resin.

An electrically conductive shield layer 42 is preferably formed on a surface of the electronic component 10 by using an electrically conductive resin. The shield layer 42 preferably is continuously formed as a single layer over a top surface 20a and side surfaces 20s of the first resin layer 20, the side surfaces 12s of the substrate 12, and portions 30p of side surfaces 30s of the second resin layer 30, which are located on sides closer to the substrate 12. A portion 30q of the side surface 30s of the second resin layer 30, which is located on a far side of the substrate 12, and a side surface 42s of the shield layer 42 are formed in such a way that the portion 30q and the side surface 42s are in the same plane.

The shield layer 42 is formed so as to provide a space between the shield layer 42 and the bottom surface 30b of the second resin layer 30. That arrangement allows insulation between the outer electrodes 34 and the shield layer 42 to be secured. Thus, the shield layer 42 may be easily and securely insulated from another circuit board or the like, to which the electronic component 10 is mounted through the outer electrodes 34.

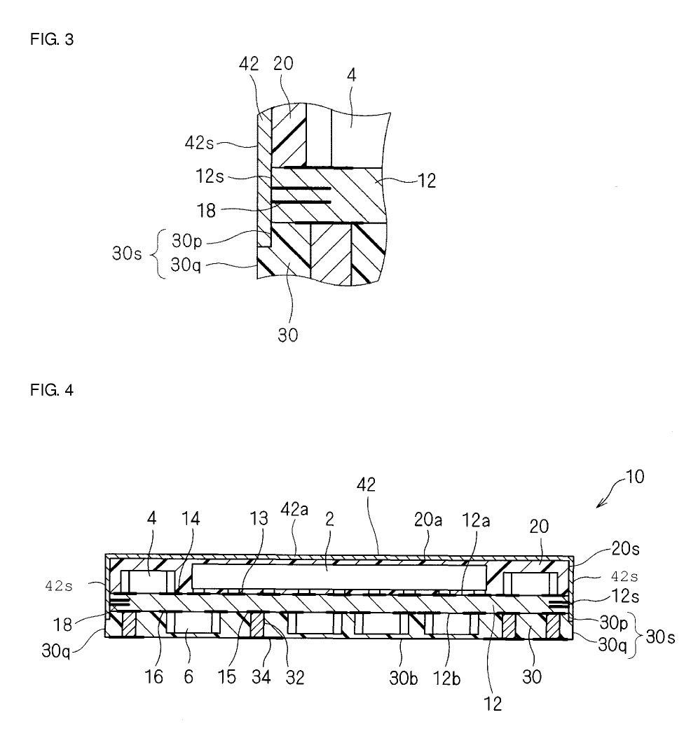

As illustrated in an enlarged cross-sectional diagram of FIG. 3, the shield layer 42 is in contact with and electrically connected to the ground electrodes 18 that reach the side surface 12s of the substrate 12. Thus, it is not necessary to form any ground electrode on the top surface 12a of the substrate 12 to connect with an uppermost surface portion 42a of the shield layer 42 via a connection terminal penetrating through the first resin layer 20. This facilitates more flexibility in designing of the substrate 12.

The shield layer 42 is electrically conductive and, as illustrated in FIG. 4, formed so as to cover surroundings of the electronic components 2, 4 mounted on the top surface 12a of the substrate 12 and buried inside the first resin layer 20. Accordingly, the electronic components 2, 4 may be protected against penetration and/or leakage of electromagnetic waves (electric fields, magnetic fields, or both).

Although it is not illustrated in the drawing, in an alternative configuration, the shield layer 42 may be in contact with and electrically connected to a bottom surface side ground electrode pattern that is formed on the bottom surface 12b of the substrate 12 and reaches an outer edge of the side surface 12s of the substrate 12. In still another alternative configuration, the shield layer 42 may be in contact with and electrically connected to a top surface side ground electrode pattern that is formed on the top surface 12a of the substrate and reaches an outer edge of the side surface 12s of the substrate 12.

The closer the ground electrodes 18, which are to be in contact with the shield layer 42, are arranged to the bottom surface 12b within the substrate 12, the better the shielding characteristics become for the electronic components 2, 4 mounted on the top surface 12a of the substrate 12. The best shielding characteristics may be obtained for the electronic components 2, 4 when the shield layer 42 is in contact with a ground electrode pattern formed on the bottom surface 12b of the substrate 12. Since the second resin layer 30 is arranged on the bottom surface 12b of the substrate 12, it is possible to arrange a ground electrode on the bottom surface 12b of the substrate 12. Thus, electronic components with better characteristics may be provided.

The shield layer 42 extends up to the second resin layer 30. Thus, a shielding effect may also be obtained for the electronic component 6 arranged in the second resin layer 30.

The shield layer 42 extends from the first resin layer 20, crosses the side surface 12s of the substrate 12, and reaches the second resin layer 30. Thus, bonding strength may be enhanced. The side surface 20s of the first resin layer 20, the side surface 12s of the substrate 12, and a portion of the side surface 30s of the second resin layer 30 on the side closer to the substrate 12, to which the shield layer 42 is bonded, are preferably formed by forming a closed-bottom trench 40 (refer to FIG. 1B) from the first resin layer 20 side to the second resin layer 30. Details will be described below.

The first resin layer 20 and the second resin layer 30 are softer and more susceptible to heat than the substrate 12. Thus, of side surfaces formed in a closed-bottom trench forming step, those of the first resin layer 20 and the second resin layer 30 may have rougher surfaces than that of the substrate 12. That is, the side surface 20s of the first resin layer 20 and the portion 30p of the side surface 30s of the second resin layer 30 on the side closer to the substrate 12 may likely have rougher surfaces than the side surface 12s of the substrate 12. The bonding strength increases since a tip portion of the shield layer 42 is positioned on the substrate 12 side portion 30p of the side surface 30s of the second resin layer 30, which has the rougher surface.

A stronger bonding strength of the shield layer 42 with the first resin layer 20 and the second resin layer 30 may be obtained when the shield layer 42 includes an electrically conductive material and a resin that is the same type of material as the first resin layer 20 and the second resin layer 30.

On the other hand, when the substrate 12 is a ceramic substrate, the shield layer 42 may not adhere firmly to the ceramic substrate which is a different type of material and come off easily. When the substrate 12 is a printed substrate, the shield layer 42 may come off easily from the substrate 12 since the thermal expansion coefficient of the printed substrate in the thickness direction is larger than that of the shield layer 42.

However, the shield layer 42 is preferably formed so as to cross the side surface 12s of the substrate 12 and form relatively strong bonds with the first resin layer 20 and the second resin layer 30 at both sides of the substrate 12. Thus, the bonding strength of the shield layer may be increased compared to a case where the shield layer is formed halfway on the side surface of the substrate and the tip portion of the shield layer ends at the side surface of the substrate.

Next, a non-limiting example of a method of manufacturing the electronic component 10 is described with reference to FIGS. 1A and 1B and FIGS. 2C and 2D. FIGS. 1A and 1B and FIGS. 2C and 2D are cross-sectional diagrams illustrating manufacturing steps of the electronic component 10. The electronic component 10 is first manufactured in form of a multi-piece board and then separated into individual pieces.

First, as illustrated in FIG. 1A, the multi-piece board is prepared. In the multi-piece board, the electronic components 2, 4, 6 are mounted on the substrate 12 and covered with the resin layers 20, 30.

More specifically, after mounting the electronic components 6 on the bottom surface 12b of the substrate 12, the substrate 12 is arranged on a semi-cured resin sheet, from which the second resin layer 30 is to be formed, in such a way that one of principle surfaces of the semi-cured resin sheet faces the bottom surface 12b of the substrate 12. Furthermore, a copper foil used to form the outer electrodes 34 is arranged on the other principle surface of the semi-cured resin sheet. Subsequently, the copper foil and the semi-cured resin sheet are bonded together by thermo-compression bonding.

The resin sheet is preferably made by mixing inorganic filler (Al₂O₃, SiO₂, TiO₂, etc) into a thermosetting resin (epoxy, phenol, cyanate, etc). The state of “semi-cured” means a B-stage state or a prepreg state. By thermo-compression bonding, the semi-cured resin sheet is pressure bonded to the bottom surface 12b of the substrate 12, and at the same time fills gaps formed between the electronic components 6 and the substrate 12. Vacuuming during the pressure bonding of the resin sheet prevents production of voids in the resin.

The connection terminals 32 are formed in advance in the resin sheet by first forming through holes with a laser or the like and then filling the through holes with an electrically conductive resin (e.g., a mixture of metal particles such as Au, Ag, Cu, Ni, etc. and a thermosetting resin such as epoxy, phenol, cyanate, etc.).

When performing the thermo-compression bonding, the copper foil is aligned so as to be in contact with the connection terminal 32. Furthermore, the substrate 12 is aligned so that the terminal electrode 15 formed on the bottom surface 12b of the substrate 12 is in contact with the connection terminal 32.

The thermo-compression bonding cures the connection terminal 32 prepared in the resin sheet, and electrically connects the connection terminal 32 to the terminal electrode 15 on the bottom surface 12b of the substrate 12 as well as the copper foil, all at the same time.

After the resin sheet is thermally cured, the outer electrode 34 is formed by going through the steps of photoresist coating, exposure, developing, etching, and resist stripping to pattern the copper foil.

Subsequently, in a state where the second resin layer 30 is pressure bonded with the substrate 12 at the bottom surface 12b, the electronic components 2, 4 are mounted on the mounting electrodes 13, 14 provided on the top surface 12a of the substrate 12. Next, as is the case with the second resin layer 30, a semi-cured resin sheet, from which the first resin layer 20 is formed, is arranged on the top surface 12a of the substrate 12. Subsequently, they are subjected to thermo-compression bonding to cure the resin sheet to form the first resin layer 20.

Next, as illustrated in FIG. 1B, the closed-bottom trenches 40 are formed from the first resin layer 20 side so as to reach the second resin layer 30 along hypothetical separation lines that are drawn to separate the multi-piece board into individual boards. The closed-bottom trench 40 is formed in such a way that the closed-bottom trench 40 completely separates the first resin layer 20 and the substrate 12, and reaches the middle of the second resin layer 30.

When a ceramic substrate is cut to the middle of its thickness and this cutting process is ended there, the ceramic substrate may crack and/or break. However, the substrate 12 is cut through completely. Thus, such problems do not occur even if the substrate 12 is a ceramic substrate.

By forming the closed-bottom trench 40, the ground electrodes 18 are exposed at a cut surface of the substrate 12, namely, the side surface 12s of the substrate 12. The ground electrodes 18 are formed in advance in the substrate 12 so as to reach the vicinity of the hypothetical separation line 11 or extend across the hypothetical separation line 11.

Next, as illustrated in FIG. 2C, the shield layer 42 is formed inside the closed-bottom trench 40 and on the top surface 20a of the first resin layer 20. For example, the shield layer 42 may be formed by coating the inside of the closed-bottom trench 40 with a shield compound including an electrically conductive material and a resin, forming a thin uniform coating of the shield compound on the top surface 20a of the first resin layer 20 by spin coating, and then curing those shield compounds. Alternatively, the shield layer 42 may be formed by using a method other than the spin coating, such as coating the shield compound in vacuum.

The shield layer 42 comes in contact with the ground electrodes 18 exposed at the cut surface of the substrate 12, namely, the side surface 12s of the substrate 12, and is electrically connected to the ground electrodes 18.

Next, as illustrated in FIG. 2D, the shield layer 42 formed inside the closed-bottom trench 40 and the second resin layer 30 are cut with a dicing blade 50 or the like along the hypothetical separation line 11 to separate the multi-piece board into individual pieces. Here, the shield layer 42 formed inside the closed-bottom trench 40 is separated, and the cut surface thus separated becomes the side surface 42s of the shield layer 42.

Alternatively, break trenches may be formed in the shield layer 42 and the second resin layer 30 along the hypothetical separation lines 11, and the individual pieces may be obtained by breaking instead of cutting.

According to the steps described above, the electronic component 10 is completed.

In the present non-limiting example, the connection terminal 32 is formed by filling the through hole formed in the resin sheet with the electrically conductive resin. Alternatively, the connection terminal 32 may be formed by mounting a metal terminal such as a pin on the substrate 12 and then applying a thermo-compression bonding process to that resin sheet.

In the electronic component 10, the formation of the shield layer 42 and the connection of the shield layer 42 to the ground electrodes 18, which reach the side surface 12s of the substrate 12, are achieved at the same time. Accordingly, the step performed solely to establish an electrical connection between the shield layer and the substrate may be eliminated, and the manufacturing cost may be reduced.

### Example 2

An electronic component 10a of Example 2 will now be described with reference to FIG. 5. FIG. 5 is a cross-sectional diagram of the electronic component 10a.

As illustrated in FIG. 5, the electronic component 10a of Example 2 preferably is formed in substantially the same manner as the electronic component 10 of Example 1. Below, the same reference numerals denote the same elements as those of Example 1, and the description will focus on differences from Example 1.

The electronic component 10a of Example 2 is, when compared to the electronic component 10 of Example 1, formed such that the entirety of a side surface 30t of the second resin layer 30 forms a single plane together with the side surface 12s of the substrate 12 and the side surface 20s of the first resin layer 20, and such that a surface level difference 44t is formed between a side surface 44s of a shield layer 44 and the side surface 30t of the second resin layer 30.

The electronic component 10a may be manufactured by using substantially the same steps as those of the electronic component 10 of Example 1. That is, in the second step of manufacturing the electronic component 10 of Example 1, instead of forming the closed-bottom trench 40 up to the middle of the thickness of the second resin layer 30, the second resin layer 30 is cut through completely. After separating the multi-piece board into individual pieces, the shield layer 44 is formed as a single continuous layer that covers the first resin layer 20, the substrate 12, and a portion of the second resin layer 30 on a side closer to the substrate 12 by dipping.

In the electronic component 10a, the formation of the shield layer 44 and the connection of the shield layer 44 to the ground electrodes 18, which reach the side surface 12s of the substrate 12, are achieved at the same time. Accordingly, the step performed solely to establish an electrical connection between the shield layer and the substrate side may be eliminated, and the manufacturing cost may be reduced.

It is not necessary to form any ground electrode on the top surface 12a of the substrate 12 to connect with an uppermost surface portion 44a of the shield layer 44 via a connection terminal penetrating through the first resin layer 20. This facilitates more flexibility in designing of the substrate 12.

### Example 3

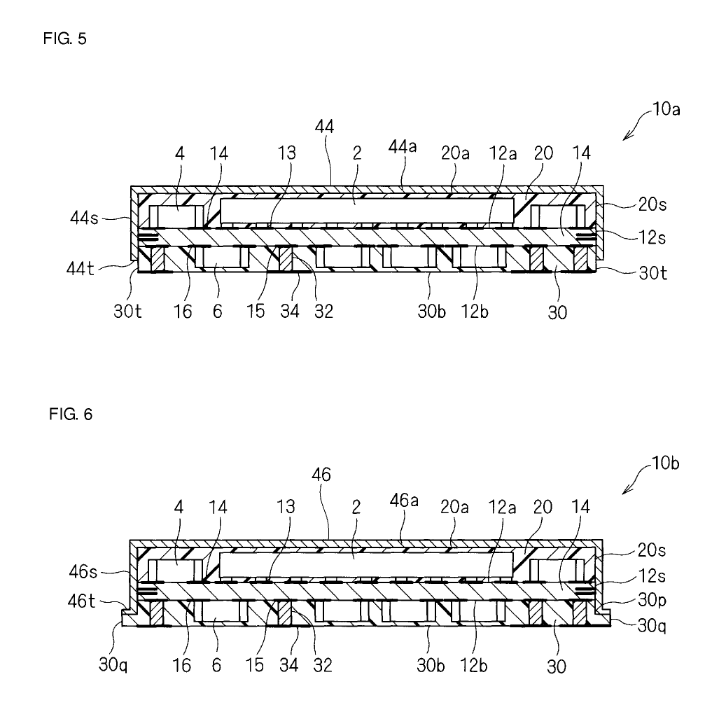

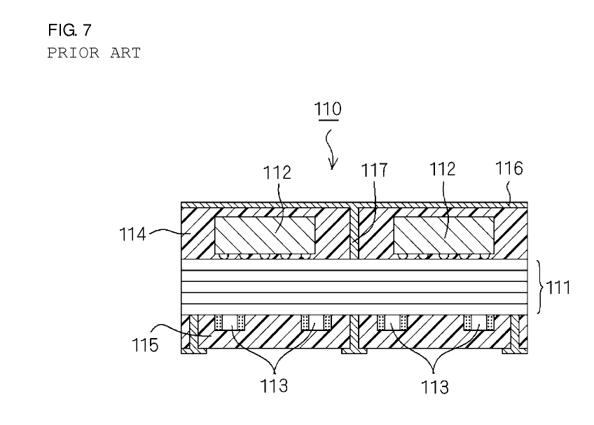

An electronic component 10b of Example 3 will now be described with reference to FIG. 6. FIG. 6 is a cross-sectional diagram of the electronic component 10b.

The electronic component 10b of Example 3 may be manufactured by using substantially the same steps as those of the electronic component 10 of Example 1. That is, the electronic component 10b preferably is manufactured by using the same steps as those of Example 1 except that a shield layer 46 is formed by sputtering in the third step of manufacturing the electronic component 10 of Example 1.

The shield layer 46 is a metal film, and thus formed to thinly cover surfaces of inner walls and the bottom of the closed-bottom trench 40. As a result, in the shield layer 46, a step surface 46t is formed along the bottom of the closed-bottom trench 40. The step surface 46t is continuous with a side surface 46s that is formed along the surface of the inner wall of the closed-bottom trench 40.

In the electronic component 10b, the formation of the shield layer 46 and the connection of the shield layer 46 to the ground electrodes 18, which reach the side surface 12s of the substrate 12, are achieved at the same time. Accordingly, the step performed solely to establish an electrical connection between the shield layer and the substrate side may be eliminated, and the manufacturing cost may be reduced.

It is not necessary to form any ground electrode on the top surface 12a of the substrate 12 to connect with an uppermost surface portion 46a of the shield layer 46 via a connection terminal penetrating through the first resin layer 20. This facilitates more flexibility in designing of the substrate 12.

Accordingly, in the electronic components according to preferred embodiments of the present invention described above, the step performed solely to establish an electrical connection between the shield layer and the substrate may be eliminated, and the manufacturing cost may be reduced. Furthermore, it is not necessary to form any ground electrode on the top surface of the substrate to connect with the uppermost surface portion of the shield layer via a connection terminal penetrating through the first resin layer. This facilitates more flexibility in designing of the substrate.

It is to be understood that the present invention is not limited to the foregoing preferred embodiments and may be implemented with various modifications.

For example, the shield layer may alternatively be formed by plating.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component comprising:
a substrate including a first principle surface, a second principle surface that faces the first principle surface, and a side surface that extends between the first and the second principle surfaces;
a first electronic component mounted on the first principle surface of the substrate;
a second electronic component mounted on the second principle surface of the substrate;
a first resin layer arranged on the first principle surface of the substrate so as to cover the first principle surface and the first electronic component;
a second resin layer arranged on the second principle surface of the substrate so as to cover the second principle surface and the second electronic component;
a shield layer that is electrically conductive and is a single continuous layer covering the first resin layer, the substrate, and a portion of the second resin layer that is adjacent to the substrate; and
a ground electrode that is arranged in the substrate so as to reach the side surface of the substrate, the ground electrode being in contact with the shield layer and electrically connected to the shield layer.

2. The electronic component according to claim 1, wherein
the second resin layer includes a first principle layer that is in contact with the second principle surface of the substrate, a second principle surface that faces the first principle surface, and a side surface that extends between the first principle surface and the second principle surface; and
the shield layer is arranged on the side surface of the second resin layer so as to provide a space between the shield layer and the second principle surface of the second resin layer.

3. The electronic component according to claim 1, wherein the shield layer includes an electrically conductive resin.

4. The electronic component according to claim 1, wherein the first electronic component and the second electronic component are one of an active device and a passive device.

5. The electronic component according to claim 1, wherein the first electronic component and the second electronic component are one of a semiconductor, a capacitor, an inductor and a resistor.

6. The electronic component according to claim 1, wherein the substrate is a ceramic multilayer substrate.

7. The electronic component according to claim 1, wherein the first resin layer and the second resin layer include a synthetic resin and an inorganic compound.

8. The electronic component according to claim 1, wherein the shield layer is in physical contact with and electrically connected to a bottom surface ground electrode pattern that is located on a bottom surface of the substrate and extends to an outer edge of the side surface of the substrate.

9. The electronic component according to claim 1, wherein the shield layer is in physical contact with and electrically connected to a top surface ground electrode pattern that is located on a top surface of the substrate and extends to an outer edge of the side surface of the substrate.

10. The electronic component according to claim 1, wherein the shield layer extends from the first resin layer, crosses the side surface, and reaches the second resin layer.

11. A method for manufacturing an electronic component, comprising:
a first step of preparing a multi-piece board including a substrate including a first principle surface and a second principle surface that faces the first principle surface; wherein
the substrate includes plural portions that are to be separated and become plural individual boards;
in each of the plural portions that become the individual boards, a ground electrode is formed so as to reach an outer edge of the portions that becomes the individual boards;
in each of the plural portions that become the individual boards, a first electronic component is mounted on the first principle surface;
in each of the plural portions that become the individual boards, a second electronic component is mounted on the second principle surface;
a first resin layer is formed on the first principle surface so as to cover the first principle surface and the first electronic component; and
a second resin layer is formed on the second principle surface so as to cover the second principle surface and the second electronic component;
a second step of forming closed-bottom trenches in the multi-piece board by cutting the first resin layer, the substrate, and a portion of the second resin layer on a substrate side from a principle surface of the first resin layer, which is on an opposite side to the substrate, so that the substrate is separated into the individual boards, the second step exposing the ground electrode at a cut surface of the substrate;
a third step that forms a shield layer inside the closed-bottom trenches and on the principle surface of the first resin layer, which is on the opposite side to the substrate, by using an electrically conductive material so that the shield layer is in contact with and electrically connected to the ground electrode that is exposed; and
a fourth step that separates the multi-piece board into individual pieces by cutting the multi-piece board along cutting lines along which the substrate is separated.

12. The method according to claim 11, wherein
the second resin layer includes a first principle layer that is in contact with the second principle surface of the substrate, a second principle surface that faces the first principle surface, and a side surface that extends between the first principle surface and the second principle surface; and
the shield layer is arranged on the side surface of the second resin layer so as to provide a space between the shield layer and the second principle surface of the second resin layer.

13. The method according to claim 11, wherein the shield layer includes an electrically conductive resin.

14. The method according to claim 11, wherein the first electronic component and the second electronic component are one of an active device and a passive device.

15. The method according to claim 11, wherein the first electronic component and the second electronic component are one of a semiconductor, a capacitor, an inductor and a resistor.

16. The method according to claim 11, wherein the substrate is a ceramic multilayer substrate.

17. The method according to claim 11, wherein the first resin layer and the second resin layer include a synthetic resin and an inorganic compound.

18. The method according to claim 11, wherein the shield layer is in physical contact with and electrically connected to a bottom surface ground electrode pattern that is located on a bottom surface of the substrate and extends to an outer edge of the side surface of the substrate.

19. The method according to claim 11, wherein the shield layer is in physical contact with and electrically connected to a top surface ground electrode pattern that is located on a top surface of the substrate and extends to an outer edge of the side surface of the substrate.

20. The method according to claim 11, wherein the shield layer extends from the first resin layer, crosses the side surface, and reaches the second resin layer.
